(19) United States
(12) Patent Application Publication
(10) Pub. No.: US 2006/0291179 A1
(43) Pub. Date: Dec. 28, 2006

(54) WIRING BOARD AND DISPLAY DEVICE

(76) Inventor: Masaru TANIMORI, Ako-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/425,866

(22) Filed: Jun. 22, 2006

(30) Foreign Application Priority Data
Jun. 23, 2005 (JP) 2005-183385

(51) Int. Cl. H05K 7/06

(52) U.S. Cl. 361/784; 361/777; 361/803

(57) ABSTRACT

A wiring board includes electrode parts which are electrically connected to a plurality of pads on an object of connection to the wiring board, wiring patterns which are connected to the electrode parts, and an alignment mark which is formed integral with at least one of the wiring patterns.

### CROSS-REFERENCE TO RELATED APPLICATIONS

This application is based upon and claims the benefit of priority from prior Japanese Patent Application No. 2005-183385, filed Jun. 23, 2005, the entire contents of which are incorporated herein by reference.

### BACKGROUND OF THE INVENTION

1. Field of the Invention

The present invention relates generally to a wiring board and a display device, and more particularly to the structure of an alignment mark which serves as a reference mark for relative positioning between a wiring board and a display panel when the wiring board and the display panel are to be connected.

2. Description of the Related Art

A flat display device includes a display panel, which has a display area for displaying an image, and a flexible printed circuit (FPC), that is, a wiring board, which is connected to the display panel. The wiring board includes an alignment mark which serves as a reference mark for relative positioning between a wiring board and a display panel when the wiring board and the display panel are to be connected. The alignment mark, for example, is formed in an insular shape on a base film of the wiring board (see, e.g. Jpn. Pat. Appln. KOKAI Publication No. 2004-109969).

When pads, which are disposed on one edge portion of the display panel, are electrically connected via an adhesive, such as an anisotropic conductive film, to electrode parts of the wiring board, displacement may occur between the pads and the electrode parts or foreign matter (in particular, electrically conductive foreign particle) may be caught therebetween. Even in the case where such a connection defect occurs, the display panel may be reused after the wiring board is peeled unless the display panel itself is defective.

However, when the wiring board is peeled from the display panel, the alignment mark on the wiring board may possibly be transferred to the display panel. In such a case, a fabrication step is required to remove the alignment mark that is transferred to the display panel. This leads to a decrease in manufacturing yield and an increase in manufacturing cost.

### BRIEF SUMMARY OF THE INVENTION

The present invention has been made in consideration of the above-described problem, and the object of the invention is to provide a wiring board which is capable of improving manufacturing yield and decreasing manufacturing cost, and a display device including the wiring board.

According to a first aspect of the present invention, there is provided a wiring board comprising: electrode parts which are electrically connected to a plurality of pads on an object of connection to the wiring board; wiring patterns which are connected to the electrode parts; and an alignment mark which is formed integral with at least one of the wiring patterns.

According to a second aspect of the present invention, there is provided a display device comprising: a display panel including a display area which displays an image; and a wiring board which is connected to the display panel, the wiring board including: electrode parts which are electrically connected to a plurality of pads disposed on one side edge portion of the display panel; wiring patterns which are connected to the electrode parts; and an alignment mark which is formed integral with at least one of the wiring patterns and serves as a reference mark for relative positioning between the display panel and the wiring board when the display panel and the wiring board are to be connected.

The present invention can provide a wiring board which is capable of improving manufacturing yield and decreasing manufacturing cost, and a display device including the wiring board.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 schematically shows the structure of a display device including a wiring board according to an embodiment of the present invention;

FIG. 2 is a cross-sectional view taken along line A-A in FIG. 1, showing a schematic cross-sectional structure of a display panel and the wiring board;

FIG. 3 is a plan view that schematically shows a structure of the wiring board shown in FIG. 2;

FIG. 4 is a cross-sectional view taken along line B-B in FIG. 3, showing a schematic cross-sectional structure of the display panel and wiring board;

FIG. 5 is a plan view that schematically shows another structure of the wiring board shown in FIG. 2; and

FIG. 6 is a cross-sectional view taken along line C-C in FIG. 5, showing a schematic cross-sectional structure of the display panel and wiring board.

### DETAILED DESCRIPTION OF THE INVENTION

A wiring board and a display device including the wiring board, according to an embodiment of the present invention, will now be described with reference to the accompanying drawings.

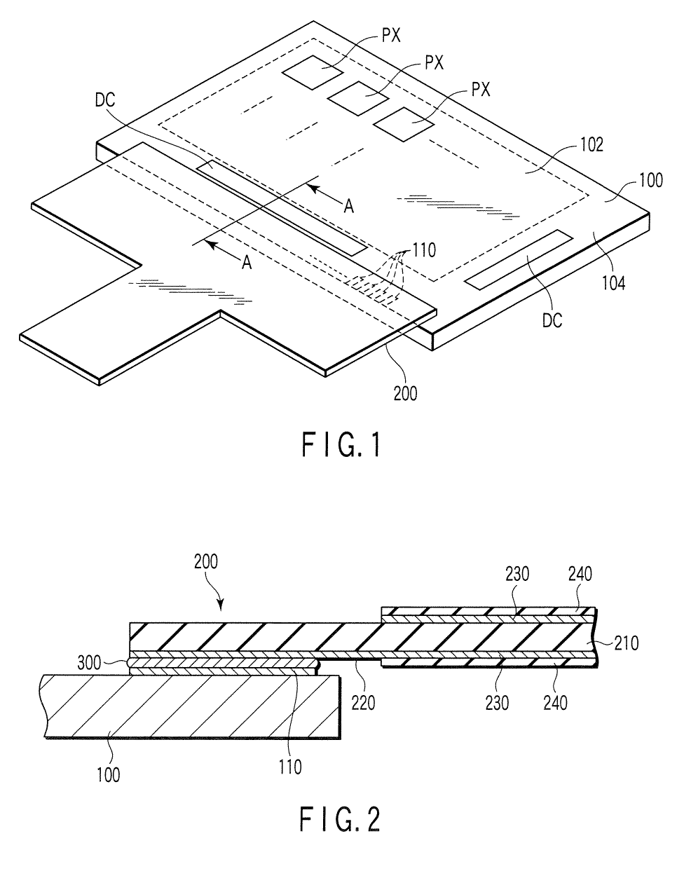

As is shown in FIG. 1 and FIG. 2, the display device includes a flat display panel (i.e. an object of connection to the wiring board) 100. The display panel 100 includes a display area 102 for displaying an image. The display area 102 is composed of a plurality of matrix-arrayed pixels PX. The display panel 100 includes, on a peripheral area 104 surrounding the display area 102, at least a part of driving circuits (e.g. a signal line driving circuit for supplying video signals to signal lines and a scan line driving circuit for supplying control signals to scan lines) DC which generate various driving signals necessary for image display. On the peripheral area 104, a plurality of pads 110 are disposed along one side edge portion of the display panel 100.

The display device includes a wiring board 200 which is connected to the display panel 100. The wiring board 200 functions to supply various signals that are necessary for displaying an image on the display panel 100. The wiring board 200 may include a control circuit in itself, or may be connected to a separate driving circuit board.

The wiring board 200 is formed by using a flexible base film 210. A plurality of electrode parts 220, which are configured to be electrically connectable to the pads 110 of the display panel 100, are disposed on one end portion of the wiring board 200. Specifically, the electrode parts 220 are disposed with a predetermined pitch, for example, by taking into account the intervals of the pads 110 of the display panel 100.

The electrode parts 220 are connected to wiring patterns 230 on the base film 210. The electrode parts 220 and wiring patterns 230 are formed of a metallic material such as copper (Cu). The surfaces of the electrode parts 220 are plated with, e.g. gold (Au). The wiring patterns 230 are covered with a cover film 240. The cover film 240 is a solid film that is formed substantially entirely over the wiring board 200. The cover film 240 is formed of a resin material such as polyimide.

The display panel 100 and wiring board 200 are electrically and mechanically connected via a connection member such as an anisotropic conductive film 300. Specifically, the pads 110 of display panel 100 and the electrode parts 220 of wiring board 200 are electrically connected by an electrically conductive material contained in the anisotropic conductive film 300 and are mechanically connected by an adhesive contained in the anisotropic conductive film 300.

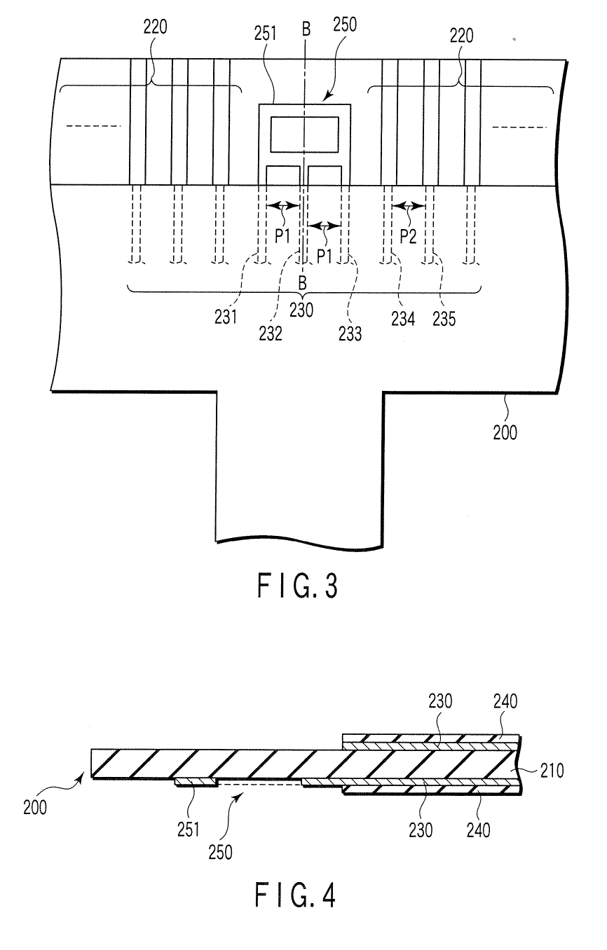

As is shown in FIG. 3 and FIG. 4, the wiring board 200 includes an alignment mark 250 which serves as a reference mark for relative positioning between the wiring board 200 and the display panel 100 when the wiring board 200 and display panel 100 are to be connected. The alignment mark 250 is configured to suppress transfer thereof to the display panel 100 when the wiring board 200 is connected to the display panel 100.

In this example, the alignment mark 250 is disposed on the base film 210 and is formed integral with at least one of the wiring patterns 230. In other words, the alignment mark 250 is not independently formed in an insular shape, but is connected to some other pattern on the wiring board 200. Thus, even if the wiring board 200 is peeled from the display panel 100 after the wiring board 200 is connected to the display panel 100, the alignment mark 250 stays on the wiring board 200 together with the wiring pattern 230 and is prevented from being transferred to the display panel 100.

The wiring pattern 230, which is formed integral with the alignment mark 250, is covered with the cover film 240. Since the cover film 240 is the solid film that is formed substantially entirely over the wiring board 200, the cover film 240 holds the wiring pattern 230 between itself and the base film 210 over a large formation area. Thus, even if the alignment mark 250 is peeled from the base film 210, the wiring pattern 230, which is formed integral with the alignment mark 250, is prevented from being peeled from the base film 210. Therefore, the transfer of the alignment mark 250 to the display panel 100 can be suppressed.

Preferably, the wiring pattern 230, which is formed integral with the alignment mark 250, should be formed on the base film 210 with a larger formation area than the alignment mark 250. Specifically, the alignment mark 250 is formed integral with a pattern with a relatively large formation area, such as a grounded wiring pattern or a pattern (e.g. an electrically floated wiring pattern) that is formed in an insular shape on the base film 210. Thereby, even if the alignment mark 250 is peeled from the base film 210, the wiring pattern 230 with a large formation area is not easily peeled and the alignment mark 250, together with the wiring pattern 230, stays on the wiring board 200 side. Therefore, the transfer of the alignment mark 250 to the display panel 100 can be suppressed. Moreover, by covering the wiring pattern 230 having the large formation area with the cover film 240, the wiring pattern 230 is further prevented from being peeled from the base film 210. Thus, the transfer of the alignment mark 250 to the display panel 100 can be suppressed.

Preferably, the alignment mark 250 should be formed of the same metallic material as the wiring pattern 230. Thereby, a separate fabrication step for forming only the alignment mark 250 is needless, and the manufacturing cost can be reduced.

Besides, the alignment 250 may be formed integral with a plurality of wiring patterns. In the example shown in FIG. 3, a main part 251 of the alignment mark 250 is formed integral with three wiring patterns 231, 232 and 233. Thereby, the alignment mark 250 is formed with wiring patterns with a relatively large formation area, and the transfer of the alignment mark 250 to the display panel 100 can be suppressed.

The wiring board 200 is formed by using the flexible base film 210. In many cases, the wiring board 200 is disposed in a bent form. If the wiring patterns 231, 232 and 233, which are formed integral with the alignment mark 250, are formed with a greater width or a smaller pitch than the other wiring patterns 234, 235 (P1<P2), the bending performance of the peripheral part of the alignment mark 250 may become poorer than that of the other parts.

It is thus desirable that the pitch PI of the three wiring patterns 231, 232 and 233 be set to be substantially equal to the pitch P2 of other wiring patters that are formed integral with the electrode parts 220, for example, wiring patterns 234 and 235 in FIG. 3. In addition, it is desirable that the wiring patterns 231 to 235 have substantially the same width. Thereby, degradation in bending performance of the wiring board 200 can be suppressed.

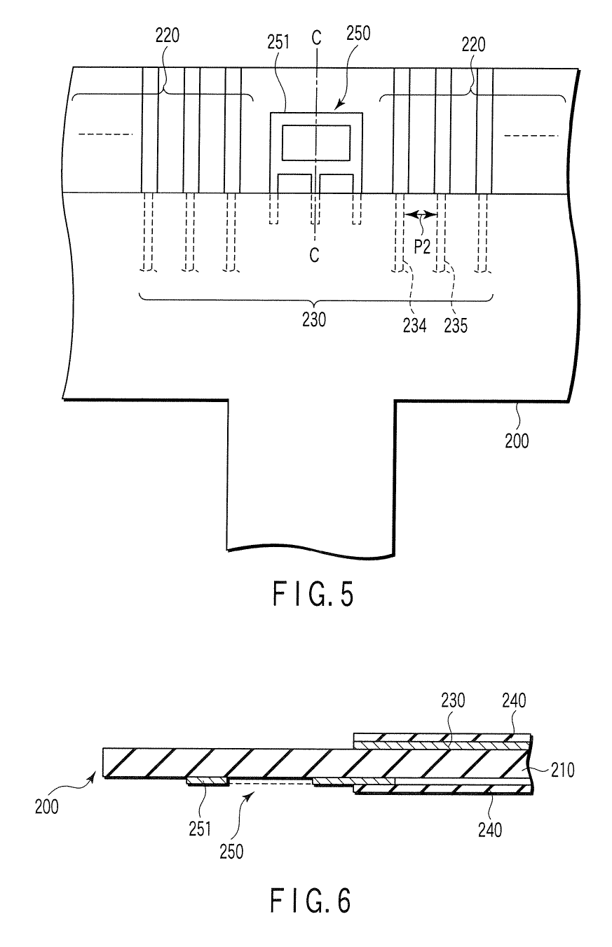

In the example shown in FIG. 3 and FIG. 4, the alignment mark 250 is formed integral with at least one of the wiring patterns 230. Alternatively, as shown in FIG. 5 and FIG. 6, the alignment mark 250 may be formed in an insular shape on the base film 210, and a part of the alignment mark 250, together with the wiring patterns 230, may be covered with the cover film 240. Since the cover film 240 is a solid film that substantially entirely covers the wiring board 200, the cover film 240 can hold the part of the alignment mark 250 between itself and the base film 210 over a large formation area. Thereby, the alignment mark 250 is not easily peeled from the base film 210, and the transfer of the alignment mark 250 to the display panel 100 can be suppressed.

The present invention is not limited directly to the above-described embodiment. In practice, the structural elements can be modified without departing from the spirit of the invention. Various inventions can be made by properly combining the structural elements disclosed in the embodiment. For example, some structural elements may be omitted from all the structural elements disclosed in the embodiment. Furthermore, structural elements in different embodiments may properly be combined.

For example, in the above-described embodiment, the display device may be a self-luminous display device such as an organic EL (electroluminescence) display device, or may be a liquid crystal display device. In the case of the organic EL display device, the display panel 100 is configured such that each of the pixels PX includes a pixel circuit and a display element that is driven and controlled by the pixel circuit. In the case of the liquid crystal display device, the display panel 100 is configured such that a liquid crystal layer is held between a pair of substrates and each of the pixels PX includes a display element, which has a liquid crystal layer held between a pixel electrode and a counter-electrode, and a switching element for writing a predetermined potential in the pixel electrode.

What is claimed is:

1. A wiring board comprising:
electrode parts which are electrically connected to a plurality of pads on an object of connection to the wiring board;
wiring patterns which are connected to the electrode parts; and
an alignment mark which is formed integral with at least one of the wiring patterns.

2. The wiring board according to claim 1, wherein the wiring patterns are covered with a cover film.

3. The wiring board according to claim 1, wherein the wiring pattern, which is formed integral with the alignment mark, is grounded.

4. The wiring board according to claim 1, wherein the alignment mark is formed integral with a plurality of said wiring patterns, and
a pitch of the wiring patterns, which are formed integral with the alignment mark, is substantially equal to a pitch of the other wiring patterns which are connected to the electrode parts.

5. A wiring board comprising:
electrode parts which are electrically connected to a plurality of pads on an object of connection to the wiring board;
wiring patterns which are connected to the electrode parts;
an alignment mark; and
a cover film which covers the wiring patterns and a part of the alignment mark.

6. A display device comprising:
a display panel including a display area which displays an image; and
a wiring board which is connected to the display panel,
the wiring board including:
electrode parts which are electrically connected to a plurality of pads disposed on one side edge portion of the display panel;
wiring patterns which are connected to the electrode parts; and
an alignment mark which is formed integral with at least one of the wiring patterns and serves as a reference mark for relative positioning between the display panel and the wiring board when the display panel and the wiring board are to be connected.
